(19) United States
(12) Patent Application Publication
(10) Pub. No.: US 2010/0244905 A1
(43) Pub. Date: Sep. 30, 2010

(54) Input buffer circuit of semiconductor device having function of adjusting input level

(76) Inventors: Jung-Sik Kim, Seoul (KR); Joung-Wook Moon, Hwaseong-si (KR)

Correspondence Address: LEE & MORSE, P.C., 3141 FAIRVIEW PARK DRIVE, SUITE 500, FALLS CHURCH, VA, 22042, US

(21) Appl. No.: 12/659,925

(22) Filed: Mar. 25, 2010

(30) Foreign Application Priority Data
Mar. 30, 2009 (KR) 10-2009-0026835

(51) Int. Cl. H03B 1/00

(52) U.S. Cl. 327/108

(57) ABSTRACT

An input buffer circuit of a semiconductor device, the input buffer circuit including a buffer, the buffer configured to adjust an input level of an input signal in response to a selected bias voltage, a voltage generating and distributing unit, the voltage generating and distributing unit configured to generate and distribute a plurality of bias voltages having different levels, and a selector, the selector configured to select from among the plurality of bias voltages according to an applied selection signal and to apply the selected bias voltage to the buffer.

### BACKGROUND

1. Field

Example embodiments relate to an input buffer circuit of a semiconductor memory device, the input buffer circuit having a function of adjusting an input level.

2. Description of the Related Art

A dynamic random access memory device (hereinafter, referred to as a ‘DRAM’) having one access transistor and one storage capacitor as a unit memory cell is generally used as the main memory of an electronic system. In the DRAM, during a data access operation, various kinds of input signals are input to a buffer in order to read or write data. For example, write data may be input as input signals to an input buffer in a write operation.

### SUMMARY

Embodiments are directed to an input buffer circuit of a semiconductor memory device, the input buffer circuit having a function of adjusting an input level, which substantially overcomes one or more of the problemS due to the limitations and disadvantages of the related art.

It is a feature of an embodiment to provide a buffer circuit capable of appropriately adjusting the level of an input signal in a semiconductor device including a buffer.

It is another feature of an embodiment to provide a semiconductor memory device in which the input level of an input signal applied to a buffer is adjusted to an optimal value by a mode register set signal or a fuse option.

It is another feature of an embodiment to provide a semiconductor device capable of improving the reliability of a buffering operation of an input buffer.

At least one of the above and other features and advantages may be realized by providing an input buffer circuit of a semiconductor device, the input buffer circuit including a buffer, the buffer configured to adjust an input level of an input signal in response to a selected bias voltage, a voltage generating and distributing unit, the voltage generating and distributing unit configured to generate and distribute a plurality of bias voltages having different levels, and a selector, the selector configured to select from among the plurality of bias voltages according to an applied selection signal and to apply the selected bias voltage to the buffer.

The selected bias voltage may be applied to the buffer as a bulk bias voltage applied to a well of the buffer.

The voltage generating and distributing unit may be configured to generate respective bias voltages for p-type and n-type transistors of the buffer, the selector may include two parts, and the two parts may respectively select bias voltages corresponding to the p-type and n-type transistors of the buffer.

At least one of the above and other features and advantages may also be realized by providing an input buffer circuit for adjusting an input level of a semiconductor device, the input buffer circuit including an input buffer, the input buffer having independent first-conduction-type and second-conduction-type wells, a voltage generating and distributing unit, the voltage generating and distributing unit configured to generate and distribute bias voltages having different levels, and a selector, the selector configured to select at least one of the bias voltages according to an applied test mode register set signal and to apply the selected at least one bias voltage as a bulk bias voltage to the first-conduction-type and second-conduction-type wells of the input buffer.

The input buffer may be an inverter-type buffer.

The voltage generating and distributing unit may be configured to generate bias voltages corresponding to p-type and n-type transistors of the input buffer, the selector may include two parts, and the two parts may respectively select bias voltages corresponding to the p-type and n-type transistors of the input buffer.

At least one of the above and other features and advantages may also be realized by providing an input buffer circuit for adjusting an input level of a semiconductor device, the input buffer circuit including an input buffer, the input buffer having independent first-conduction-type and second-conduction-type wells, a voltage generating and distributing unit, the voltage generating and distributing unit being configured to generate and distribute bias voltages having different levels, and a selector, the selector configured to select at least one of the bias voltages according to a fuse option signal and to apply the selected at least one bias voltage as a bulk bias voltage to the first-conduction-type and second-conduction-type wells of the input buffer.

The first-conduction-type well may be an n-type well and the second-conduction-type well may be a p-type well.

At least one of the above and other features and advantages may also be realized by providing a semiconductor device, including an input buffer circuit, the input buffer circuit configured to buffer an input signal and including an input buffer having a plurality of inverters, the inverters being connected in parallel and having respectively different driving capabilities, the inverters each including second-conduction-type transistors and first-conduction-type transistors respectively disposed in independent first-conduction-type and second-conduction-type wells, a voltage generating and distributing unit, the voltage generating and distributing unit configured to generate and distribute bias voltages having different levels, and a selector, the selector configured to select at least one of the bias voltages according to a mode register set signal or a fuse option signal and to apply the selected at least one bias voltage to control transistors, the control transistors being configured to control operations of the input buffer such that the inverters selectively participate in buffering the input signal.

Control transistors of two different conduction types may be provided in each of the inverters.

### BRIEF DESCRIPTION OF THE DRAWINGS

The above and other features and advantages will become more apparent to those of skill in the art by describing in detail example embodiments with reference to the attached drawings, in which:

FIG. 1 illustrates a block diagram of a data processing system including a DRAM to which an input buffer circuit according to example embodiments may be applied;

FIG. 2 illustrates a block diagram of the structure of the DRAM shown in

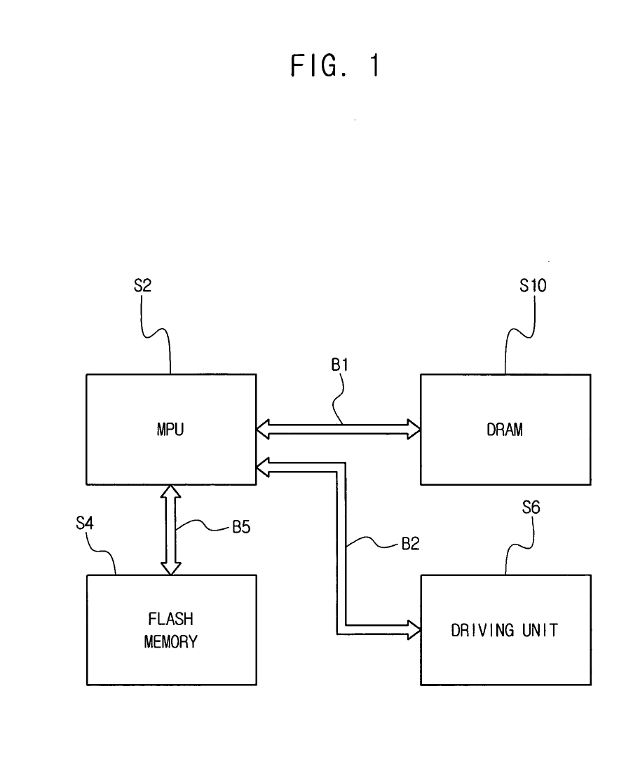

FIG. 1;

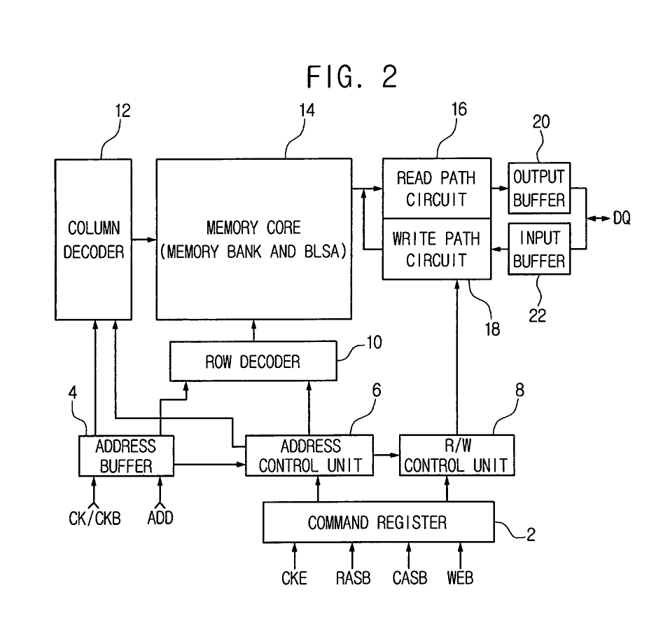

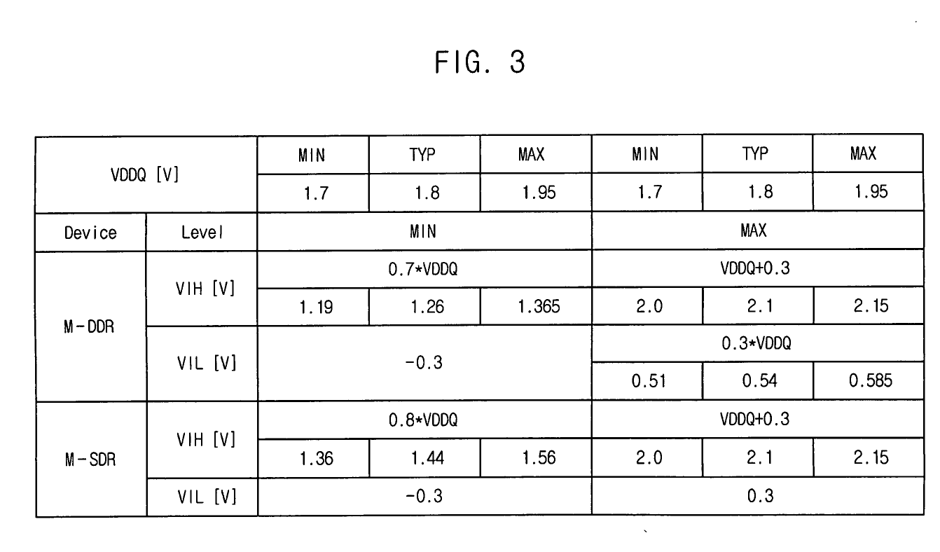

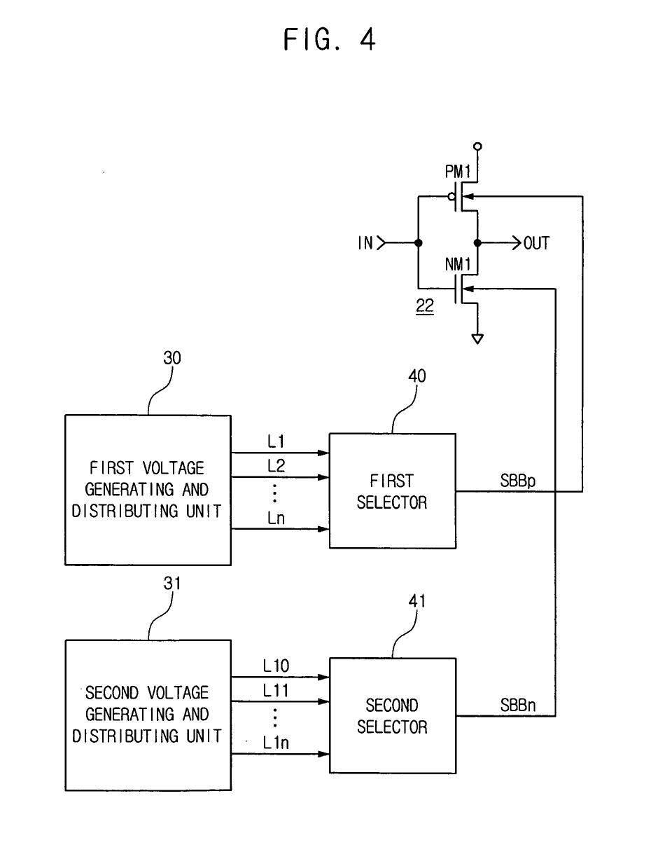

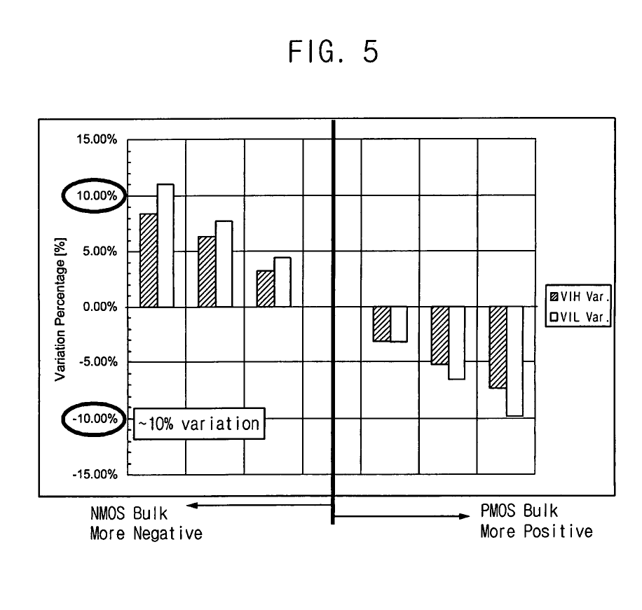

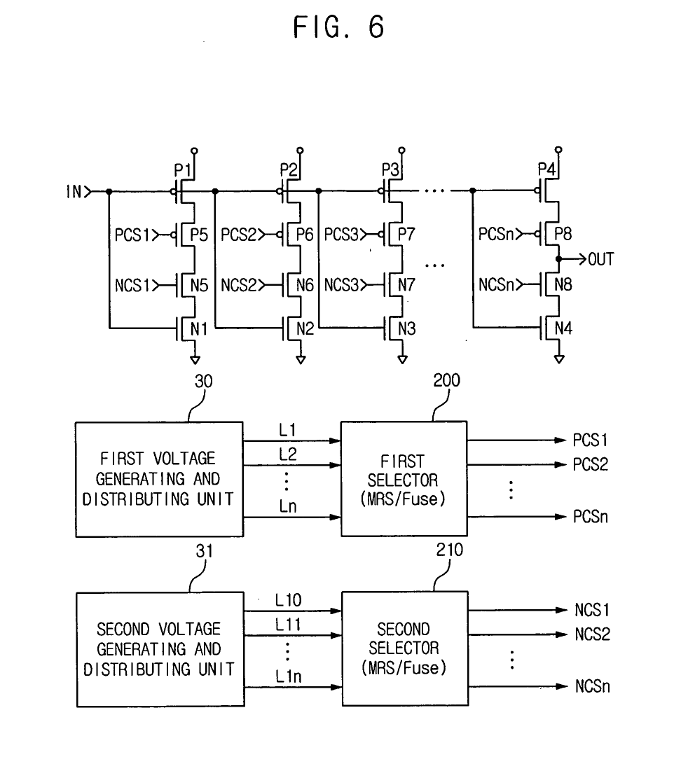

FIG. 3 illustrates a table of the levels of various input signals applied to an input buffer shown in FIG. 2;

FIG. 4 illustrates a diagram of an input buffer circuit according to an example embodiment, in which an input level of the input signal may be adjusted in accordance with a selected bulk bias voltage;

FIG. 5 illustrates a diagram of a variation in the input level of an input signal when the bulk bias of an input buffer shown in FIG. 4 varies; and

FIG. 6 illustrates a diagram of an input buffer circuit according to another example embodiment, in which the input buffer includes a plurality of inverters and the number of inverters participating in the buffering operation is adjustable.

### DETAILED DESCRIPTION

Korean Patent Application No. 10-2009-0026835, filed on Mar. 30, 2009, in the Korean Intellectual Property Office, and entitled: “Input Buffer Circuit of Semiconductor Device Having Function of Adjusting Input Level,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. Like reference numerals refer to like elements throughout.

It will be understood that, although the terms first, second and third may be used herein to describe various elements, these elements should not be limited by) these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular embodiments only and is not intended to be limiting of example embodiments. As used herein, the singular forms “a,” “an,” and “the” are intended to include the plural forms as well, unless the context clearly indicates otherwise. It will be further understood that the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belongs. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Hereinafter, an input buffer circuit having a function of adjusting an input level according to example embodiments of the invention will be described with reference to the accompanying drawings.

FIG. 1 illustrates a block diagram of a data processing system including a DRAM to which an input buffer circuit according to example embodiments may be applied.

FIG. 2 illustrates a block diagram of the structure of the DRAM shown in FIG. 1, and FIG. 3 illustrates a table of the levels of various input signals applied to an input buffer shown in FIG. 2.

The block diagram of FIG. 2 shows the wiring relationship among general functional blocks, to which example embodiments described herein may be applied. Referring to FIG. 2, the DRAM may include a command register 2, an address buffer 4, an address control unit 6, a read/write control unit 8, a row decoder 10, a column decoder 12, a memory core 14, a read path circuit 16, a write path circuit 18, an output buffer 20, and an input buffer 22.

The command register 2 may receive a clock enable signal CKE, a row address strobe signal RASB, a column address strobe signal CASB, and a write enable signal WEB, and may output command signals to the address control unit 6 and the read/write control unit 8.

The address buffer 4 may store an applied address ADD in response to a clock CK/CKB, and may allocate the address ADD as a row address and a column address to the row decoder 10 and the column decoder 12, respectively.

The memory core 14 may include a bit line sense amplifier connected to a bit line pair, and a memory cell array including a plurality of memory banks in which memory cells MC each having one access transistor AT and one storage capacitor SC are arranged in a matrix so as to correspond to intersections of word lines and bit lines.

The address control unit 6 may generate addresses for data access and may control a refresh operation for retaining data.

The row decoder 10 may be connected to the address control unit 6 and the memory core 14, and may perform row address decoding to activate a selected word line.

The column decoder 12 may receive the column address and may output a column selection signal for selecting the bit lines connected to the memory cells of the memory core 14.

The read path circuit 16 and the write path circuit 18 may include input/output lines, a plurality of amplifying circuits, precharge units, and buffers. In an example implementation, the read path circuit 16 and the write path circuit 18 include local input/output line precharge units, local sense amplifiers, global sense amplifiers, and global/local input/output line drivers.

The output buffer 20, the input buffer 22, the read path circuit 16, and the write path circuit 18 may be included in a data path circuit.

The input buffer 22 may buffer an input signal, such as write data, that is input through a terminal DQ. However, if the level of the input signal is out of a predetermined margin, an error may occur in the buffering operation.

For example, in a DDR memory, when an input signal of 1.18 V is applied, an error occurs in the buffering operation since the level is lower than 1.19 V, which is the minimum level of the high input voltage VIH, as shown in FIG. 3. In this case, even though write data is input at a high level, the write data is buffered at a low level.

FIG. 3 shows the levels of various input signals applied to the input buffer 22 shown in FIG. 2.

In FIG. 3, M-DDR indicates a double data rate memory and M-SDR indicates a single data rate memory.

As shown in FIG. 3, the level of the low input voltage VIL or the high input voltage VIH applied to the input buffer 22 may vary depending on various applications, such as MCP (multi chip package), POP (package on package), and SIP (system in package). In addition, the level of the input signal may vary according to a PVT (process, voltage, and temperature) variation.

Therefore, in order to improve the reliability of the buffering operation, the levels of the input signals should be appropriately adjusted according to particular application or the PVT variation.

As described below in connection with FIG. 4, an example embodiment provides an input buffer circuit configured to appropriately adjust the level of the input signal in, for example, a semiconductor memory device that includes a buffer.

FIG. 4 illustrates a diagram of an input buffer circuit according to an example embodiment, in which an input level of the input signal may be adjusted in accordance with a selected bulk bias voltage.

Referring to FIG. 4, the input buffer circuit may include an input buffer 22, first and second voltage generating and distributing units 30 and 31, and first and second selectors 40 and 41.

The input buffer 22 may be an inverter type buffer that includes a PMOS transistor PM1 and an NMOS transistor NM1. The input level of an input signal IN may be adjusted in accordance with a selected bias voltage applied to the input buffer 22. For example, the input level of the input signal IN may be adjusted by respective selected bulk bias voltages that are applied to the bulk of each of the PMOS and NMOS transistors PM1 and NM1.

The PMOS and NMOS transistors PM1 and NM1 may be respectively formed in independent first-conduction-type (for example, n-type) and second-conduction-type (for example, p-type) wells.

The first voltage generating and distributing unit 30 may generate and distribute bias voltages L1, L2, . . . , Ln having different levels with respect to the PMOS transistor PM1.

The second voltage generating and distributing unit 31 may generate and distribute bias voltages L10, L11, . . . , L1n having different levels with respect to the NMOS transistor NM1.

The first selector 40 may select one of the bias voltages L1, L2, . . . , Ln, which are output from the first voltage generating and distributing unit 30, according to an applied selection signal. The first selector 40 may apply the selected bias voltage as a bias voltage SBBp to the bulk of the PMOS transistor PM1. The applied selection signal may be, e.g., a mode register set signal, a test mode register set signal, a metal option signal, or a fuse option signal.

The second selector 41 may select one of the bias voltages L10, L11, . . . , L1n, which are output from the second voltage generating and distributing unit 31, according to an applied selection signal. The second selector 41 may apply the selected bias signal as a bias voltage SBBn to the bulk of the NMOS transistor NM1. In an implementation, the selection signal applied to the second selector 41 may be the same as the selection signal applied to the first selector 40.

The bias voltage SBBp selected by the first selector 40 may be applied to the bulk of the PMOS transistor PM1 and may be used to adjust a bulk bias. The bias voltage SBBn selected by the second selector 41 may be applied to the bulk of the NMOS transistor NM1 and may be used to adjust a bulk bias.

According to the example embodiment described above in connection with FIG. 4, the input level of the input signal IN that is received by the input buffer 22 may be adjusted to an optimal value before being output from the input buffer circuit. The input level may be adjusted in accordance with, e.g., a mode register set signal, a fuse option, etc. Therefore, the reliability of the buffering operation of the input buffer may be improved.

FIG. 5 illustrates a diagram of a variation in the input level of an input signal when the bulk bias of an input buffer shown in FIG. 4 varies.

In FIG. 5, the horizontal axis indicates the bulk bias of the NMOS and PMOS transistors and the vertical axis indicates the variation percentages of the low input voltage VIL and the high input voltage VIH. As illustrated in FIG. 5, as a magnitude of a negative bias voltage that is applied to the NMOS bulk increases, the variation percentage of VIL may increase by, for example, 10%.

FIG. 6 illustrates a diagram of an input buffer circuit according to another example embodiment, in which the input buffer includes a plurality of inverters and the number of inverters participating in the buffering operation is adjustable. According to the example embodiment described below, the input level of an input signal applied to a buffer may be adjusted to an optimal value by, e.g., a mode register set signal, a fuse option, etc. Therefore, the reliability of the buffering operation of the input buffer may be improved.

Referring to FIG. 6, an input buffer circuit according to the present example embodiment may include an input buffer having a plurality of inverters. The inverters may be connected in parallel. Each of the inverters may include second-conduction-type transistors P1, P2, P3, and P4 and first-conduction-type transistors N1, N2, N3, and N4 that have different sizes and are formed in independent first-conduction-type (n-type) and second-conduction-type (p-type) wells. Each of the inverters may include a second-conduction-type transistor and a first-conduction-type transistor. For example, a first inverter may include the second-conduction-type transistor P1 and the first-conduction-type transistor N1. In addition, turn-on/turn-off control transistors P5, N5, P6, N6, P7, N7, P8, and N8 may be connected to the plurality of inverters. For example, the control transistors P5 and N5 may be connected between the channels of the PMOS and NMOS transistors P1 and N1 of the first inverter. The sizes of the transistors may be adjusted such that the inverters have different driving capabilities.

The control transistor P5 may be turned on or off in response to a first p-type control signal PCS1, and the control transistor N5 may be turned on or off in response to a first n-type control signal NCS1.

When the control transistors P5 and N5 are both turned on, the inverter including the PMOS and NMOS transistors P1 and N1 may be driven. Thus, the inverter including the PMOS and NMOS transistors P1 and N1 may participate in the buffering operation. In this case, the level of the input signal is adjusted according to whether the inverter including the PMOS and NMOS transistors P1 and N1 is driven.

Similarly, when the control transistors P6 and N6 are both turned on, the inverter including PMOS and NMOS transistors P2 and N2 may be driven. Thus, the inverter including PMOS and NMOS transistors P2 and N2 may participate in the buffering operation. In this case, the level of the input signal is adjusted according to whether the inverter including the PMOS and NMOS transistors P2 and N2 is driven.

As described above in connection with FIG. 6, an input buffer circuit according to the present example embodiment may include an input buffer having a plurality of inverters, which may each have different driving capabilities. The number of inverters participating in the buffering operation may be adjusted by turning on or off the control transistors corresponding to the inverters.

In further detail, referring to FIG. 6, the first voltage generating and distributing unit 30 may generate and distribute bias voltages L1, L2, . . . , Ln with independent levels for driving the PMOS transistors P1, P2, P3, and P4 of the inverters.

The second voltage generating and distributing unit 31 may generate and distribute bias voltages L10, L11, . . . , L1n with independent levels for driving the NMOS transistors N1, N2, N3, and N4 of the inverters.

A first selector 200 may select from among the bias voltages L1, L2, . . . , Ln, which are output from the first voltage generating and distributing unit 30, according to a selection signal. The first selector 200 may apply the selected bias voltages as on/off control signals to the gates of the control transistors P5, P6, P7, and P8. The selection signal may include, e.g., a mode register set signal, a test mode register set signal, a metal option signal, or a fuse option signal.

A second selector 210 may select from among the bias voltages L10, L11, . . . , L1, which are output from the second voltage generating and distributing unit 31, according to a selection signal. In an implementation, the selection signal applied to the second selector 210 may be the same as the selection signal applied to the first selector 200. The second selector 210 may apply the selected bias voltages as on/off control signals to the gates of the control transistors N5, N6, N7, and N8.

As described above, the number of inverters participating in the buffering operation may be adjusted by the selection signal. Thus, it may be possible to adjust the input level of the input signal applied to the input terminal IN and output a signal having the adjusted level.

As described above in connection with FIG. 6, the inverters may have different driving capabilities. However, each of the inverters may be designed to have a same driving capability.

A DRAM including the input buffer circuit shown in FIG. 4 or 6 may be used in the data processing system shown in FIG. 1.

Referring again to FIG. 1, which illustrates the data processing system including the DRAM to which the input buffer circuit according to the example embodiments may be applied, the DRAM S10 may be connected to a micro processing unit S2 through a system bus B1. The DRAM S10 may serve as a main memory. The micro processing unit S2 of the data processing system may be connected to a flash memory S4 through a system bus B5. The micro processing unit S2 may perform a set processing operation according to the program stored in the flash memory S4. In addition, the micro processing unit S2 may control a driving unit S6 through a control bus B2. When controlling the driving unit S6, the micro processing unit S2 may perform a data access operation of writing data to the memory cell of the DRAM S10 and reading the written data from the memory cell for a processing operation.

Since the input level of the input signal applied to the input buffer of the DRAM S10 may be adjusted by, e.g., the mode register set signal or the fuse option, it may be possible to improve the operation reliability of the DRAM in the data processing system.

As described above, an input buffer circuit may appropriately adjust the level of an input signal in, e.g., a semiconductor memory device. In the above-described example embodiments, the DRAM is given as an example. However, the feature of the input buffer circuit may be applied to other volatile memories, such as SRAMs or pseudo SRAMs, or to non-volatile memories, such as flash memories. The levels of the input signals applied to the input buffer, e.g., the levels of a low input voltage VIL and a high input voltage VIH, may be adjusted according to various applications, such as MCP (multi chip package), POP (package on package), and SIP (system in package). In addition, the levels of the input signals may be appropriately adjusted according to a PVT (process, voltage, and temperature) variation.

Example embodiments have been disclosed herein, and although specific terms are employed, they are used and are to be interpreted in a generic and descriptive sense only and not for purpose of limitation. For example, the detailed circuit structure of the voltage generating and distributing unit or the selector may be changed and the connection structure of the transistors of the input buffer may be changed without departing from the technical scope of the invention. Accordingly, it will be understood by those of ordinary skill in the art that various changes in form and details may be made without departing from the spirit and scope of the present invention as set forth in the following claims.

What is claimed is:

1. An input buffer circuit of a semiconductor device, the input buffer circuit comprising:
a buffer, the buffer configured to adjust an input level of an input signal in response to a selected bias voltage;
a voltage generating and distributing unit, the voltage generating and distributing unit configured to generate and distribute a plurality of bias voltages having different levels; and
a selector, the selector configured to select from among the plurality of bias voltages according to an applied selection signal and to apply the selected bias voltage to the buffer.

2. The input buffer circuit as claimed in claim 1, wherein the selected bias voltage is applied to the buffer as a bulk bias voltage applied to a well of the buffer.

3. The input buffer circuit as claimed in claim 2, wherein:
the voltage generating and distributing unit is configured to generate respective bias voltages for p-type and n-type transistors of the buffer,
the selector includes two parts, and
the two parts respectively select bias voltages corresponding to the p-type and n-type transistors of the buffer.

4. An input buffer circuit for adjusting an input level of a semiconductor device, the input buffer circuit comprising:
an input buffer, the input buffer having independent first-conduction-type and second-conduction-type wells;
a voltage generating and distributing unit, the voltage generating and distributing unit configured to generate and distribute bias voltages having different levels; and
a selector, the selector configured to select at least one of the bias voltages according to an applied signal and to apply the selected at least one bias voltage as a bulk bias voltage to the first-conduction-type and second-conduction-type wells of the input buffer.

5. The input buffer circuit as claimed in claim 4, wherein the input buffer is an inverter-type buffer.

6. The input buffer circuit as claimed in claim 4, wherein:
the voltage generating and distributing unit is configured to generate bias voltages corresponding to p-type and n-type transistors of the input buffer,
the selector includes two parts, and
the two parts respectively select bias voltages corresponding to the p-type and n-type transistors of the input buffer.

7. The input buffer circuit as claimed in claim 4, wherein the applied signal is a test mode register set signal or a fuse option signal.

8. The input buffer circuit as claimed in claim 7, wherein the first-conduction-type well is an n-type well and the second-conduction-type well is a p-type well.

9. A semiconductor device, comprising:
an input buffer circuit, the input buffer circuit configured to buffer an input signal and including:
an input buffer having a plurality of inverters, the inverters being connected in parallel and having respectively different driving capabilities, the inverters each including second-conduction-type transistors and first-conduction-type transistors respectively disposed in independent first-conduction-type and second-conduction-type wells;
a voltage generating and distributing unit, the voltage generating and distributing unit configured to generate and distribute bias voltages having different levels; and
a selector, the selector configured to select at least one of the bias voltages according to a mode register set signal or a fuse option signal and to apply the selected at least one bias voltage to control transistors, the control transistors being configured to control operations of the input buffer such that the inverters selectively participate in buffering the input signal.

10. The semiconductor memory device as claimed in claim 9, wherein control transistors of two different conduction types are provided in each of the inverters.
